(19) United States
(12) Patent Application Publication
(10) Pub. No.: US 2014/0273480 A1
(43) Pub. Date: Sep. 18, 2014

(54) METHOD FOR PRODUCING A SUBSTRATE PROVIDED WITH EDGE PROTECTION

(71) Applicants: STMICROELECTRONICS SA, MONTROUGE (FR); COMMISSARIAT A L'ENERGIE ATOMIQUE ET AUX ENERGIES ALTERNATIVES, PARIS (FR)

(72) Inventors: Bernard PREVITALI, Grenoble (FR); Christian ARVET, Bernin (FR)

(21) Appl. No.: 14/218,380

(22) Filed: Mar. 18, 2014

(30) Foreign Application Priority Data
Mar. 15, 2013 (FR) 1300609

(51) Int. Cl. H01L 21/311

(52) U.S. Cl. CPC H01L 21/31105
USPC 438/703

(57) ABSTRACT

The method for producing a substrate provided with protection of its edges has a first step which is providing a substrate having a semiconductor material base. The substrate has opposite first and second main surfaces connected by a lateral surface. A first layer made from first protective material is then formed so as to coat the substrate. The first protective material is then etched on the lateral surface leaving a pattern of first protective material at least partially covering each of the first and second surfaces, and a second protective layer made from second protective material is then formed on the lateral surface devoid of the first protective material. After formation of the second protective layer, the first protective material is eliminated from the substrate.

### BACKGROUND OF THE INVENTION

The invention relates to semiconductor substrates designed to be used in the electronics, optics or optoelectronics field.

### STATE OF THE ART

The incessant increase of the performances of integrated circuits is necessarily resulting in a continuous improvement of the technological fabrication steps. Furthermore, the current microelectronics technology is based on the use of substrates, commonly called wafers, made from semiconductor material. Fabrication of high-quality substrates devoid of crystallographic and topographic defects constitutes the first important brick for achieving microelectronic devices with enhanced performances.

The Czochralski (Cz) method, for example, is currently well optimized and enables substrates having a good crystallographic quality to be fabricated on a large scale. The efforts made to improve the quality of the initial substrates, from a technical point of view, are therefore increasingly focussed on the mechanical aspects of fabrication, in particular, the topography of the substrate and the shape of its edges, which have been identified as being parameters able to impact the yield and quality of the integrated circuit fabrication method.

FIG. 1 illustrates the geometric shape of a usual substrate 1 made from semiconductor material, used in the microelectronics field. Substrate 1 comprises flat front and rear surfaces 2 and 3. The substrates are generally in the shape of a disk having a diameter which may be up to 300 mm according to current standards for fabricating integrated circuits on a large scale.

Front surface 2 comprises an active surface Sa on which different technological steps will subsequently be performed, in particular to form devices on the micrometric or nanometric scale, or to perform molecular bonding with another substrate. Front surface 2 also comprises an edge exclusion surface Eₑ. The width Lₑₑ of the edge exclusion surface is about 2 to 3 mm.

The surface of substrate 1 further comprises a lateral surface Eᵣₒ provided with a chamfer or edge roll-off. Lateral surface Eᵣₒ joins front and rear surfaces 2 and 3 to one another. The width of lateral surface L, is generally about 0.5 mm. The object of lateral surface Eᵣₒ is to facilitate handling of the substrate and to prevent edge breakage which could occur for salient edges.

However, the edges of the substrates generate several problems which are detrimental to the efficiency of the technological fabrication methods. What is meant by edge of a substrate is the part of the substrate formed by the lateral surface Eᵣₒ and the edge exclusion surface Eₑ. For example purposes, when transfer of films is performed by molecular bonding, the edges of the bulk substrates used can be responsible for the appearance of non-bonding areas, trenches, pitting, etc.

FIG. 2 illustrates a substrate of SOI type produced by molecular bonding, using for example a usual substrate of FIG. 1. The SOI substrate generally comprises a silicon film 2′ forming the front surface, separated from a support 3′ by an oxide layer 4.

According to the example illustrated in FIG. 2, the edges of the substrates can, when a substrate of SOI type is produced, further be responsible for formation of a fin 5 of silicon film 2′ at the level of edge (Eᵣₒ and Eₑ) of the wafer.

On account of the shape of the edges of conventional or SOI substrates, several contamination problems and topographical anomalies have been observed when performing conventional methods for fabricating devices on a micrometric or nanometric scale.

### OBJECT OF THE INVENTION

The object of the invention is to provide a method for producing an improved substrate, in particular comprising a protected edge, enabling topographical anomalies in the substrate to be minimized.

This object tends to be achieved by providing a method for producing a substrate made from semiconductor material comprising the following steps:
providing a substrate having a semiconductor material base, the substrate comprising opposite first and second main surfaces joined by a lateral surface;
forming a first layer made from first protective material coating the substrate;
etching the first protective material on the lateral surface leaving a pattern of first protection material at least partially covering each of the first and second surfaces;
forming a second layer made from second protective material on the lateral surface;
eliminating the first protective material.

According to an advantageous implementation, the first protective material is further etched on a peripheral area of the first surface adjacent to the lateral surface. The second layer made from second protective material is then formed on the lateral surface and on said peripheral area.

Preferably, the substrate consecutively comprises: a support comprising the second main surface, an electrically insulating layer, and a layer made from semiconductor material comprising the first main surface. Furthermore, the second protective material covers the lateral surface of the electrically insulating layer.

Furthermore, according to other advantageous and non-restrictive features:
formation of the first layer made from the first protective material is preceded by formation of a preliminary layer of silicon oxide coating the substrate;
the second protective layer is made from silicon oxide formed by oxidation;
the method comprises a lithography step defining the peripheral area;
elimination of the first protective material is followed by production of a field effect transistor on the first surface of the substrate.

### BRIEF DESCRIPTION OF THE DRAWINGS

Other advantages and features will become more clearly apparent from the following description of particular embodiments of the invention given for non-restrictive example purposes only and represented in the appended drawings, in which:

FIG. 1 represents a conventional semi-conductor substrate of bulk type, in schematic manner, in cross-sectional view;

FIG. 2 represents a conventional semi-conductor substrate of SOI type, in schematic manner, in cross-sectional view;

FIGS. 3 to 6 represent fabrication steps of a substrate according to a first embodiment, in schematic manner, in cross-sectional view;

FIGS. 7A and 7B represent a semiconductor substrate produced according to another embodiment, in schematic manner, respectively in cross-sectional view and in top view;

FIGS. 8 to 11 represent fabrication steps of a substrate according to another embodiment, in schematic manner, in cross-sectional view;

FIGS. 12 and 13 represent semi-conductor substrates fabricated according to other embodiments, in schematic manner, in cross-sectional view.

### DESCRIPTION OF PREFERRED EMBODIMENTS OF THE INVENTION

In the field of substrates designed for fabrication of micro- and nanoelectronic and/or optoelectronic components, a requirement exists to produce substrates that are more resistant to the technological steps, which enables the yield of the technological method for fabricating integrated circuits to be increased. This requirement tends to be met by providing a method for fabricating an improved substrate, provided with a protected edge.

According to a first embodiment illustrated from FIG. 3, the method comprises provision of a substrate 10 with a semiconductor material base. Substrate 10 comprises opposite first 11 and second 12 main surfaces joined by a lateral surface 13. First 11 and second 12 surfaces and lateral surface 13 thus form the outer surface of substrate 10.

Surfaces 11 and 12 are respectively called front surface and rear surface of substrate 10. The front surface of a usual substrate is moreover polished and is designed to undergo different treatments and processes to form micro- or nanoelectronic devices on said front surface.

Preferably, substrate 10 is a blank substrate having substantially parallel and flat surfaces 11 and 12. What is meant by blank substrate is a substrate that has not undergone etching or implantation or other steps designed to produce a device on its front surface. What is meant by lateral surface is a surface joining surfaces 11 and 12 of substrate 10.

Lateral surface 13 is formed by a first chamfer 13a, a bevel 13b and a second chamfer 13c. Bevel 13b is in a substantially perpendicular plane to the planes of surfaces 11 and 12. Chamfer 13a is a surface of substrate 10 which constitutes an edge roll-off between surface 11 and bevel 13b. In similar manner, chamfer 13c constitutes an edge roll-off between surface 12 and bevel 13b.

In the case where substrate 10 is devoid of bevel 13b, in other words the substrate has an edge having a rounded shape, lateral surface 13 is formed by first 13a and second 13c chamfers only. In this case, the intersection point between lateral surface 13 and a plane (not shown) substantially perpendicular to the planes of surfaces 11 and 12 and tangent to the curvature of lateral surface 13, will be equivalent to bevel 13b to define surfaces 13a and 13c.

Substrate 10 can further comprise several-stacked layers of different semi-conductor materials, for example a support covered by a layer forming surface 11. The layer forming surface 11 is made from crystalline semi-conductor material that is able to be single-crystal or polycrystalline. Preferably, surface 11 of substrate 10 is made from single-crystal semi-conductor material. The semiconductor material can have a base formed by silicon, germanium, silicon-germanium alloy, or any other relaxed or strained, intrinsic or doped, semiconductor material.

As illustrated in FIG. 4, the method also comprises a step of formation of a first layer 14 on substrate 10. Layer 14 is made from a first protective material, and it is formed in such a way as to coat substrate 10. In other words, layer 14 covers the whole outer surface of substrate 10.

After substrate 10 has been covered by layer 14, a partial etching step of this layer is then implemented. FIG. 5 represents substrate 10 after etching of the first protective material on lateral surface 13 of substrate 10. This etching step is performed so as to leave a pattern (11′ and 12′) made from first protective material at least partially covering each of first 11 and second 12 surfaces. Etching of the first protective material on lateral surface 13 can be performed by any known means compatible with the material of substrate 10 and of layer 14. For example, this partial etching can be performed by depositing a photosensitive material such as a resin on substrate 10, and by then performing a trimming step of the resin by photolithography, designed to remove the resin on lateral surface 13. Removing the resin is then followed by etching of the protective material on lateral surface 13.

The etching step is performed by any known technique enabling the first protective material to be etched, such as dry etching, wet etching, etc. Preferably, the first protective material is etched at least on the part of lateral surface 13 comprised between surface 11 and bevel 13b. Advantageously, the etching step enables the first protective material to be etched on the whole of lateral surface 13. The etching step is performed in such a way that a portion of layer 14 is always disposed on surfaces 11 and 12 of substrate 10 after etching. Layer 14 is at least partially, and preferably completely, etched on lateral surface 13.

As illustrated in FIG. 6, a second layer 15 made from second protective material is formed on lateral surface 13 devoid of the first protective material. The second protective material is thus preferably arranged on at least first chamfer 13a in order to protect this region during the future technological steps that will be undergone by surface 11. In advantageous manner, the second protective material is arranged on lateral surface 13 in its entirety.

Advantageously, lateral surface 13 is devoid of the first protective material so that the second protective material is in direct contact with the substrate, here with the semiconductor material layer. As a variant, a reduced thickness of the first protective material exists under the second protective material. If the thickness is small, the first protective material is weakly etched due to the capillarity forces which oppose penetration of an etching agent.

After formation of second protective material layer 15, the remaining first protective material is then eliminated over the whole surface of substrate 10. The method for fabricating substrate 10 thus enables a substrate to be obtained having surface 11 (the front surface) and surface 12 free, as well as edge 13 covered by the second protective material.

According to an advantageous embodiment illustrated in FIGS. 7A and 7B, the first protective material is also etched on a peripheral area Sp of first surface 11 adjacent to lateral surface 13. First surface 11 comprises an active surface Sa and peripheral area Sp. Active surface Sa is designed to subsequently undergo different technological steps, for example to produce devices on the micro- or nanometric scale. Layer 15 of second protective material is then formed on lateral surface 13 and the whole of said peripheral area Sp of first surface 11. As illustrated in FIG. 7B, protective layer 15 forms a continuous and closed ring which covers the edge of substrate 10, in other words lateral surface 13 of the substrate and a peripheral area Sp of main surface 11 and preferably a peripheral area of surface 12.

What is meant by peripheral area is a peripheral surface having an area that is considerably smaller than the total area of surface 11. The width Lₚ of peripheral area Sp is 2 to 3 mm and corresponds to the edge exclusion surface arranged on the front surface of conventional substrates of bulk type or of SOI type (cf. FIG. 1).

The method for fabricating substrate 10 advantageously enables a substrate having at least a part of its edge covered by a protective material to be obtained. Providing a protected wafer edge can prevent formation of parasite silicided areas on the edge of the wafer, in particular on lateral bevel 13b of substrate 10, if a silicidation step is performed. This advantageously enables generation of a source of metallic and particle contamination to be avoided when the technological steps are sequentially performed using different pieces of equipment.

Furthermore, fabrication of field effect transistors on substrates made from semiconductor material can comprise a lateral isolation step of Shallow Trench Isolation (STI) type. These STI operations in particular comprise a step of etching of the trenches followed by a step of deposition of an insulator and chemical planarization of the insulator. Provision of a substrate having a protected edge advantageously prevents accidental formation of a parasite trench at the level of the wafer edge and subsequent deposition of the insulator in this trench. Furthermore, this type of parasite trench can be responsible for the non-uniformity of the thicknesses of the STI isolations. Additionally, protection of the edge of the wafer enables the uniformity of the surfaces of the substrate polished by Chemical Mechanical Polishing (CMP) to be enhanced. In a CMP step, the existence of a parasite insulator trench the dimensions of which have not been mastered can in fact give rise to a problem of non-uniformity of polishing: certain areas of the substrates will be excessively polished in comparison with other areas.

According to a second embodiment, substrate 10 is a substrate of Silicon On Insulator (SOI) type. As illustrated in FIG. 8, SOI substrate 10 consecutively comprises:
a support 10a comprising second main surface 12;
an electrically insulating layer 10b; and
a layer of semiconductor material 10c comprising first main surface 11.

Electrically insulating layer 10b is made from a different material than the material of support 10a. Support 10a can further comprise several layers made from different materials. Support 10a can be a bulk silicon substrate or, depending on the applications, another type of material, for example a substrate made from germanium, silicon-germanium alloy, or any other relaxed or strained, intrinsic or doped, semiconductor material.

Electrically insulating layer 10b is designed to electrically insulate support 10a and semiconductor material layer 10c. Electrically insulating layer 10b can have a base formed by silicon oxide or silicon nitride or other electrically insulating materials.

Layer 10c is made from crystalline semiconductor material. The semi-conductor material can have a base formed by silicon, germanium, silicon-germanium alloy, or any other relaxed or strained, intrinsic or doped semi-conductor material. Layer 10c is preferably made from silicon, electrically insulating layer 10b is made from silicon oxide, and support 10a is a bulk silicon substrate.

Furthermore, the edge of semiconductor material layer 10c extends beyond the edge of electrically insulating layer 10b, at the level of the edge of substrate 10, thereby forming a fin 10d. The length of the fin can be up to 100 μm, in other words a portion of layer 10c with a length of about 100 μm which is not located on layer 10b. Formation of this type of fins in SOI substrates can be attributed to the edge effects of the substrates used for fabricating the SOI substrate. The lateral surface of substrate 10 being defined as the surface joining parallel and opposite, substantially flat surfaces 11 and 12, lateral surface 13 is then formed by (of. FIG. 8):
the lateral surface of support 10a, in other words surfaces 13a, 13b and 13c as defined for the bulk substrate of FIG. 3; and
the lateral surface of fin 10d, comprising the lateral surface of layer 10c of semiconductor material and the lateral surface of electrically insulating layer 10b.

In the case of a substrate 10 of SOI type (cf. FIG. 9), protective layer 14 is formed so as to cover the lateral surfaces of electrically insulating layer 10b and of semiconductor material layer 10c. In other words, whether it be for a substrate of SOI type or of bulk type, layer 14 is formed in such a way as to cover the whole surface of substrate 10.

FIG. 10 illustrates substrate 10 after a partial etching step of layer 14. The first protective material is etched on lateral surface 13 of substrate 10. This etching step is performed so as to leave a pattern 11′ or 12′ of first protective material and least partially covering each of first 11 and second 12 surfaces. Etching of the first protective material on lateral surface 13 can be performed by any means compatible with the materials of SOI substrate 10 and of layer 14. Etching can be dry or wet, isotropic or anisotropic etching or a succession of several types of etching. The etching step is further performed in such a way as to leave first layer 14 on first 11 and second 12 surfaces of substrate 10, at least on their central portions.

Preferably, the first protective material is at least partially etched on the part of lateral surface 13 comprised between surface 11 and bevel 13b of support 10a. In other words, the first protective material is etched on the surface of fin 10d and on the surface of first chamfer 13a of support 10a. Advantageously, the first protective material is etched on the whole of lateral surface 13. In more advantageous manner, the etching step further comprises elimination of fin 10d. As in previous embodiment, it is possible to leave a thin layer of the first protective material on lateral surface 13.

After etching, layer 15 of second protective material is formed on lateral surface 13 which has been devoid of first protective material. In the case of SOI substrate 10 (FIGS. 8 and 9), the second protective material is formed in such a way that layer 15 covers the lateral surface of electrically insulating layer 10b. The second protective material thus advantageously enables the recess formed by fin 10d to be filled. In similar manner, after formation of second protective layer 15, the remaining first protective material is then eliminated over the whole surface of SOI substrate 10.

The method for fabricating substrate 10 according to the second implementation mode advantageously enables a substrate to be obtained provided with an edge at least partially covered by a protective material. The second protective material enables the recess created by fin 10d to be advantageously filled in, thereby eliminating an important source of particle contamination which could be constituted by fin 10d in the future technological steps. The method further prevents any parasite silicidation by covering the lateral surface of semiconductor material layer 10c. This lateral surface remaining uncovered, it could be silicided thereby generating an additional source of metallic contamination.

Furthermore, the improved substrate 10 of SOI type prevents tear-off of fin 10d during a chemical mechanical polishing (CMP) step. Generation of scratches and a residual particles which a torn-off fin could generate is thus avoided.

Formation of protective layer 15 on the lateral surface located between surface 11 and lateral bevel 13b in advantageous manner enables the difference of level that exists between first surface 11 and the support substrate to be reduced. The uniformity of the CMP could thus be improved. Indeed, the absence of the SOI film and of the buried oxide on the lateral surface of a conventional SOI substrate can give rise to a problem of non-uniformity of polishing, a problem usually referred to as dishing. Indeed, when a CMP step is performed on this type of substrate, certain areas in particular at the level of the lateral surface can be excessively polished in comparison with other areas.

Fabrication of field effect transistors on substrates made from semiconductor material of bulk type or of semiconductor on insulator type generally comprises formation of shallow trench isolations STI. The edge of the substrate not being able to be protected during the lithography step, a parasite trench can then be formed at the level of the edge of substrate 10. When deposition of the insulator is performed, this parasite trench can be responsible for the non-uniformity of the thicknesses of the lateral isolations and for the increase of the problem of non-uniformity of polishing in a possible CMP step.

The method according to another particular embodiment advantageously comprises a lithography step defining peripheral area Sp, for example, a photolithography step followed by etching defining peripheral area Sp. A layer of resin can be spread on first surface 11 of substrate 10, after formation of first protective layer 14. The thickness of the resin is chosen so as to be sufficient for elimination of the first protective material. The resin can then be trimmed using for example a solvent-based chemical technique, or an optic technique in two steps: exposure followed by development, or a combination of the two techniques. When trimming of the resin is performed, substrate 10 is arranged on a support so that second surface 12 is in contact with said support. The trimming step is performed so as to keep active surface Sa of first surface 11 covered by the resin and to define peripheral surface Sp in which the resin is eliminated. The layer of resin is thus eliminated from edge 13 of substrate 10 and peripheral surface Sp.

When the etching step of the first protective material is performed, active surface Sa of surface 11 is protected by the layer of resin, and surface 12 is protected due to its contact with said substrate support. The etching step thus enables peripheral area Sp to be defined and the first protective material to be simultaneously eliminated from this area and from edge 13 of substrate 10. Depending on the etching technique used, the first protective material will be eliminated on a part or the whole of edge 13 of substrate 10.

The first and second protective materials used, and their thicknesses, will furthermore be chosen by the person skilled in the trade so as to facilitate the formation and etching steps and to be compatible with the technological method to which the protected substrate will be subjected. First layer 14 is advantageously made from silicon nitride.

In the micro- or nanotechnology field, silicon nitride is a material that is widely used for its physical properties of electric insulation and passivation. Silicon nitride is a material that constitutes an efficient diffusion barrier for oxidizing elements such as oxygen. Silicon nitride is thus advantageously used as an oxidation masking layer in micro- or nanoelectronics, which enables selective oxidations to be easily performed on a silicon-based substrate. Furthermore, the formation techniques of a silicon nitride layer are mastered and enable depositions with a very good quality (thickness, homogeneity, etc.) to be obtained.

The silicon nitride of layer 14 is preferably deposited by Low Pressure Chemical Vapor Deposition (LPCVD). Advantageously, elimination of the silicon nitride, after formation of layer 15, is performed by wet etching with an orthophosphoric acid (H₃PO₄) base.

In advantageous manner and as illustrated in FIG. 12, formation of first layer 14 of first protective material is preceded by formation of a preliminary layer 14′ of silicon oxide coating substrate 10.

Preferably, substrate 10, in particular surfaces 11 and 12, are silicon-based, and formation of preliminary layer 14′ is performed by oxidation. Preliminary layer 14′ can be formed for example by High Temperature Oxide (HTO), or from tetraethylorthosilicate (TEOS oxide), etc. Depending on the technique used to form preliminary layer 14′, a planarization step could be required. Preliminary layer 14′ of silicon oxide has a reduced thickness, preferably comprised between 5 and 50 nm.

The thickness of preliminary layer 14′ is chosen so as to prevent, or at least to minimize, generation of mechanical stresses and of crystalline defects in the semiconductor material of substrate 10. Formation of layer 14, for example made from silicon nitride, on substrate 10 can in fact generate a mechanical deformation of substrate 10 and create dislocations in the crystalline material of main surface 11. The thickness of preliminary layer 14′ is therefore dependent on the thickness of layer 14 to be deposited.

Preliminary layer 14′ advantageously enables contamination of active surface Sa located on surface 11 of substrate 10 in the course of the protection method to be prevented. Protection of the edge of substrate 10 can therefore be advantageously performed respecting and protecting the main surface of the substrate (first surface 11). Additionally, preliminary layer 14′ can also act as etch stop layer of etching of the first protective material, thereby facilitating performing of the protection method.

In advantageous manner, second layer 15 is made from silicon oxide, and substrate 10 is preferably silicon-based. The silicon oxide is advantageously an electrically insulating material compatible with silicon, and silicon nitride. Preferably, the silicon oxide of layer 15 is formed by oxidation, a technique that is easy to implement and that enables a silicon oxide of very good quality to be obtained, in particular in comparison with hydrofluoric acid-based chemical etching.

According to an alternative embodiment, second protective layer 15 can be formed by full wafer deposition of silicon oxide, performed by HTO or TEOS.

Deposition is then followed by a CMP planarization step having the silicon nitride layer, i.e. first protective layer 14, as stop layer.

Additionally, deposition of a polysilicon layer (not shown in the figures) can be performed on first protective layer 14. The polysilicon layer can have a thickness ranging from 5 to 200 nm. A planarization step of the polysilicon layer with stopping on first layer 14 is then performed. The planarization step is followed by oxidation of the portion of the polysilicon layer remaining on edge 13 of substrate 10. This embodiment can be advantageously useful when substrate 10 is germanium-based.

Furthermore, in the case where substrate 10 has a base formed by a semi-conductor material other than silicon, second protective layer 15 advantageously has a base formed by an oxide of said semiconductor material of substrate 10. For example, for a germanium- or arsenic-based substrate 10, protective layer 15 can respectively have a base formed by germanium oxide (GeO₂) or by an arsenic oxide (AsO, As₂O₃, . . . ).

According to a particular embodiment illustrated in FIG. 13, a field effect transistor 16 is produced on the first main surface 11 of substrate 10, after formation of second protective layer 15 and elimination of the first protective material. Field effect transistor 16 can be produced by means of a conventional method.

For example, after elimination of preliminary layer 14′ and/or total elimination of the first protective material, a gate stack 16g can be formed on a conduction channel. Gate stack 16g can comprise a gate dielectric layer and a layer of electrically conducting material. Furthermore, the conduction channel is defined in such a way as to be arranged on surface 11 of substrate 10, between source and drain regions 16sd. An ion implantation step can then be implemented to form source and drain regions 16sd in substrate 10. Contact connections made from electrically conducting material are then formed on gate stack 16g and on source and drain regions 16sd. According to a more advantageous embodiment, electrical insulations of STI type are formed on surface 11 of substrate 10, after total elimination of the first protective material and before formation of field effect transistor 16.

The thickness of second layer 15 is a further advantageously adjusted so as to uniformize the general topology of first surface 11 of substrate 10 in particular to facilitate the subsequent CMP steps. The thickness of layer 15 is thus adjusted according to the depth of the trenches, the thickness of deposited silicon oxide, and the consumption of the material on edge 13 of substrate 10. In advantageous manner, the thickness of second protective layer 15 is determined so as to minimize the step between main surface 11 and said layer 15. The thickness of the latter is preferably estimated at twice the maximum thickness of the stack of layers made on first surface 11 before a first CMP step, plus an estimation of the thickness of the second protective material able to be consumed during possible cleaning steps.

Additionally, in the case of a SOI substrate, the thickness of electrically insulating layer 10b is advantageously taken into consideration for an efficient adjustment of the thickness of second layer 15. For example, for SOI substrates having a buried oxide (BOX) layer with a thickness of about 145 nm, designed for producing fully depleted field effect transistors (FDSOI), the thickness of second oxide layer 15 is preferentially about 460 nm. This thickness is advantageously about twice the sum of the thicknesses of the BOX and of the stack of layers made on the SOI film. This thickness is estimated so as to make the level of the edge of the substrate correspond with the peak of the gates of the FDSOI transistors covered by an oxide layer, thereby enabling the uniformity of the global topology of first surface 11 of substrate 10 to be improved when a possible CMP step is performed.

Furthermore, the formation technique of second layer 15 is advantageously chosen according to the targeted thickness. In preferential manner, second layer 15 of silicon oxide is produced by oxidation. The oxidation type and temperature will be chosen according to the thickness of oxide to be formed.

According to a preferred exemplary embodiment:
substrate 10 is a silicon-based substrate;
preliminary layer 14′ is a thin layer of silicon oxide (SiO₂);
first protective layer 14 is made from silicon nitride (Si₃N₄); and
second protective layer 15 is made from silicon oxide (SiO₂).

Preliminary layer 14′ of silicon oxide is formed on substrate 10 by oxidation, preferably thermal oxidation either in the presence of oxygen or in the presence of water vapour. The thickness of preliminary layer 14′ is further dependent on first layer 14 of silicon nitride that is sought to be deposited. The person skilled in the trade is able to choose the thickness of preliminary layer 14′ of oxide (commonly called pedestal oxide or sacrificial oxide) necessary to receive a first layer 14 of silicon nitride so as not to generate mechanical stresses and dislocations in substrate 10.

Preferably, preliminary layer 14′ of silicon oxide has a thickness comprised between 5 and 10 nm. This layer is designed to receive a first layer 14 of silicon nitride having a thickness comprised between 50 and 150 nm.

According to this exemplary embodiment, the silicon nitride of protective layer 14 is advantageously deposited by LPCVD to guarantee efficient masking when formation of second layer 15 of silicon oxide takes place. The person skilled in the trade is able to determine the thickness of silicon nitride layer 14 according to the thickness of layer 15 to be formed on edge 13 of substrate 10. For example purposes, for a thickness of about 500 nm of second SiO₂ layer 15, Si₃N₄ layer 14 can have a thickness comprised between 80 and 100 nm. In this exemplary embodiment, the first Si₃N₄ protective layer has a thickness of about 80 nm.

Furthermore, the silicon nitride can be deposited by Plasma Enhanced Chemical Vapor Deposition (PECVD). This type of deposition is able to be envisaged for fairly small thicknesses of layer 15, for example comprised between 10 and 50 nm.

Etching of the silicon nitride on peripheral area Sp and on edge 13 of substrate 10 is advantageously performed using lithography etching. A usual layer of resin is thus spread on first surface 11 of substrate 10. The thickness of the resin will be determined according to the thickness of layer 14 of silicon nitride to be etched. For example, for a silicon nitride layer having a thickness of about 80 to 100 nm, the resin layer preferably has a thickness comprised between 100 and 200 nm.

Trimming of the resin layer is performed by chemical means and/or optic means. In advantageous manner, a combination of these two types of trimming is used in order to guarantee total elimination of the resin on the areas of substrate 10 it is desired to etch, especially when substrate 10 is a substrate of SOI type comprising a fin 10d.

In the case of a bulk substrate 10, etching of first layer 14 is advantageously a physical etching in isotropic mode. Furthermore, deoxidation of substrate 10 by diluted hydrofluoric acid (HF) is advantageously performed, before substrate 10 is placed in the etching reactor. Substrate 10 is arranged on a support, which is generally a support with electrostatic contact. Substrate 10 is arranged so that second surface 12 is in contact with said support. First protective layer 14 arranged on second surface 12 of substrate 10 is thus protected and will not be etched. N₂/CF₄/O₂ gases are advantageously used in the etching reactor to create a plasma and to etch the silicon nitride in isotropic manner. Etch stop is performed for example by detecting preliminary layer 14′ of silicon oxide by luminescence of the plasma. Isotropic etching advantageously enables the silicon nitride to be eliminated on the whole of edge 13, with a very good selectivity of the silicon nitride with respect to the silicon oxide of about 1:20.

Additionally, etching in anisotropic mode can also be performed to eliminate the silicon nitride formed on bulk substrate 10. Preliminary layer 14′ of silicon oxide forms the etch stop layer, the etching being produced using the CF₂F₂/O₂/He gases to form the plasma in the etching reactor. The anisotropy of the etching enables the silicon nitride to be eliminated on first (upper) chamfer 13a. However, the silicon nitride on bevel 13b and on second (lower) chamfer 13c may not be eliminated by the anisotropic etching.

In the case of a SOI substrate 10, several etching modes can be used. SOI substrate 10 in fact comprises a buried oxide layer which can also act as etch stop layer. Substrate 10 can further comprise a fin 10d which requires an additional treatment to eliminate the silicon nitride located underneath this fin. In advantageous manner, etching of the silicon nitride on SOI substrate 10 is performed so as to further eliminate the part of the SOI film forming fin 10d.

Several etchings can then follow one another changing the etch stop conditions of the silicon nitride and of the silicon each time. Anisotropic etchings can be implemented using CF₂F₂/O₂/He gases for formation of the plasma. Etch stop is performed by detecting the material at the end of etching by luminescence of the plasma. The etchings can thus have as stop layer either the silicon oxide of preliminary layer 14′, or the silicon of substrate 10, or buried oxide 10b. Isotropic over-etching can further be performed to eliminate the silicon nitride located underneath fin 10d of SOI substrate 10.

After the etching step, the resin layer is eliminated, for example by a plasma formed from the gases O₂/N₂. Treatment by plasma is advantageously followed by wet chemical etching using the SC1 solution at low temperature (SC1 standing for Standard Clean 1). Depending on the etch stop layer used in the silicon nitride etching step, the chemical etching can be selective with respect to the silicon oxide of preliminary layer 14′, or with respect to the silicon of substrate 10, or with respect to the silicon oxide of buried layer 10b.

Silicon oxide layer 15 is then produced by oxidation, preferably by thermal oxidation, on edge 13 of substrate 10. According to the targeted oxide thickness, thermal oxidation performed at a temperature ranging from 700 to 1050° C. can be implemented. The thermal oxidation can also be a dry oxidation in the presence of oxygen, or wet oxidation in the presence of water vapour, etc. The silicon nitride is then eliminated from the surface of substrate 10 using a conventional orthophosphoric acid-based (H₃PO₄) wet etching.

1-8. (canceled)

9. A method for producing a substrate comprising the following steps:
providing a substrate having a semiconductor material base, the substrate comprising opposite first and second main surfaces joined by a lateral surface;
forming a first layer, made from first protective material, coating the substrate;
etching the first protective material on the lateral surface leaving first and second patterns of first protection material at least partially covering the first and second main surfaces respectively;
forming a second layer made from second protective material on the lateral surface devoid of the first protective material;
eliminating the first protective material.

10. The method according to claim 9, wherein the first protective material is further etched on a peripheral area of the first main surface, the peripheral area being adjacent to the lateral surface, and wherein the second layer of second protective material is then formed on the lateral surface and on said peripheral area.

11. The method according to claim 9, wherein the substrate consecutively comprises:
a support comprising the second main surface;
an electrically insulating layer provided with an additional lateral surface;
a layer made from semiconductor material comprising the first main surface;
and wherein the second protective material covers the additional lateral surface of the electrically insulating layer.

12. The method according to claim 9, wherein the first layer is made from silicon nitride.

13. The method according to claim 12, wherein formation of the first layer made from the first protective material is preceded by formation of a preliminary layer of silicon oxide coating the substrate.

14. The method according to claim 9, wherein the second layer is made from silicon oxide, formed by oxidation.

15. The method according to claim 10, comprising a lithography step defining the peripheral area.

16. The method according to claim 9, wherein after elimination of the first protective material, a field effect transistor is produced on the first main surface of the substrate.
